(19) United States
(12) Patent Application Publication
(10) Pub. No.: US 2019/0393253 A1
(43) Pub. Date: Dec. 26, 2019

(54) IMAGE SENSOR

(71) Applicant: Commissariat à l'Énergie Atomique et aux Énergies Alternatives, Paris (FR)

(72) Inventor: Yvon Cazaux, Grenoble (FR)

(73) Assignee: Commissariat à l'Énergie Atomique et aux Énergies Alternatives, Paris (FR)

(21) Appl. No.: 16/445,361

(22) Filed: Jun. 19, 2019

(30) Foreign Application Priority Data
Jun. 20, 2018 (FR) 1855447

(51) Int. Cl. H01L 27/146; H04N 5/378

(52) U.S. Cl. CPC H01L 27/14614; H04N 5/378

(57) ABSTRACT

An image sensor including a plurality of pixels, each pixel including a photogate detector coupled to a readout circuit via a first conductive transfer gate, wherein the photogate detector and the first transfer gate are formed inside and on top of a first semiconductor substrate, and the readout circuit is formed inside and on top of a second semiconductor substrate arranged on the first substrate, the sensor being intended to be illuminated on the side of the surface of the first substrate opposite to the second substrate.

This application claims the priority benefit of French patent application number 18/55447, filed on Jun. 20, 2018, the content of which is hereby incorporated by reference in its entirety to the maximum extent allowable by law.

### BACKGROUND

The present disclosure relates to the field of image sensors. It more particularly aims at image sensors formed in sequential 3D technology.

### DISCUSSION OF THE RELATED ART

An image sensor conventionally comprises a plurality of pixels, for example, arranged in an array of rows and columns, each pixel comprising a photodiode and a readout circuit comprising one or a plurality of transistors.

To increase the integration surface density of the pixels while keeping a significant photodetection surface area per pixel and thus a high sensitivity, it has been provided to form image sensors on two stacked semiconductor levels. As an example, patent application US2007/0018075 describes a sensor where, in each pixel, the photodiode and a readout circuit selection transistor are formed inside and on top of a first semiconductor substrate, the rest of the readout circuit being formed inside and on top of a second semiconductor substrate stacked on the first substrate.

To limit the required alignment accuracy on transfer of the second substrate to the first substrate, it is particularly provided in patent application US2007/0018075 to first form the photodiodes and the access transistors inside and on top of the first semiconductor substrate, to then deposit the second substrate on the first substrate, and then only to form the rest of the readout circuit inside and on top of the second substrate. Such a manufacturing technology is generally called sequential 3D technology (“3D” for three dimensions since the sensor is formed on a plurality of semiconductor levels, and “sequential” since the components of the upper semiconductor substrate are formed only after having formed the components of the lower semiconductor substrate and transferred the upper substrate onto the lower substrate).

A problem which is posed on forming of an image sensor in sequential 3D technology is that the pixel elements formed inside and on top of the first semiconductor substrate are exposed to a relatively high additional thermal budget during the forming of the pixel elements formed inside and on top of the second semiconductor substrate. This may in particular result in degrading the performance of the sensor photodiodes. In particular, in the above-mentioned patent application US2007/0018075, the photodiodes of the pixels are so-called pinned photodiodes, each formed of a stack of a little diffused heavily P-type doped region located at the surface of the first P-type substrate, and of an N-type buried region located under and in contact with the heavily-doped P-type region. On forming of the transistors of the second semiconductor substrate, the sensor may reach relatively high temperatures, which may range up to 1,000° C. or even more. This causes a dopant diffusion from the heavily-doped P-type region to the N-type buried region, thus modifying the profile of the dopings of the junction and degrading the performance of the photodiode.

### SUMMARY

An object of an embodiment is to overcome all or part of the disadvantages of known image sensors formed in sequential 3D technology.

To achieve this, an embodiment provides an image sensor comprising a plurality of pixels, each pixel comprising a photogate detector coupled to a readout circuit via a first conductive transfer gate, wherein the photogate detector and the first transfer gate are formed inside and on top of a first semiconductor substrate, and the readout circuit is formed inside and on top of a second semiconductor substrate arranged on the first substrate, the sensor being intended to be illuminated on the side of the surface of the first substrate opposite to the second substrate.

According to an embodiment, the photogate detector comprises:
a storage region of a conductivity type opposite to that of the first substrate, formed in the first substrate;
a dielectric layer coating the storage region;
a conductive gate coating the dielectric layer.

According to an embodiment, the distance between the gate of the photogate detector and the first transfer gate is shorter than 0.5 micrometer.

According to an embodiment, the first substrate is of type P and the storage region is of type N.

According to an embodiment, the doping level of the storage region is in the range from 10¹⁷ to 10¹⁸ atoms per cm³.

According to an embodiment, the storage region is doped with arsenic.

According to an embodiment, the sensor further comprises, under the first transfer gate, a first transfer region having a conductivity type opposite to that of the first substrate, formed in the first substrate, the first transfer region being insulated from the first transfer gate by a dielectric layer.

According to an embodiment, the photogate detector is further coupled to a discharge node via a second conductive transfer gate formed on the first conductive substrate.

According to an embodiment, the sensor comprises, under the second transfer gate, a second transfer region, having a conductivity type opposite to that of the first substrate, formed in the first substrate, the second transfer region being insulated from the second transfer gate by a dielectric layer.

According to an embodiment, the distance between the gate of photogate detector and the second transfer gate is shorter than 0.5 micrometer.

According to an embodiment, the photogate detector is coupled to the readout circuit via a metallization located in an opening crossing the second substrate.

According to an embodiment, the readout circuit comprises a plurality of MOS transistors.

Another embodiment provides a method of manufacturing a sensor such as defined hereabove, comprising the successive steps of:

forming the photogate detector and a first transfer gate inside and on top of the first substrate;

depositing the second substrate on the first substrate; and forming the readout circuit inside and on top of the second substrate.

The foregoing and other features and advantages will be discussed in detail in the following non-limiting description of specific embodiments in connection with the accompanying drawings.

### BRIEF DESCRIPTION OF THE DRAWINGS

FIG. 1 is an electric diagram of an example of a pixel of an image sensor according to an embodiment;

FIG. 2 is a cross-section view schematically illustrating an embodiment of the pixel of FIG. 1;

FIG. 3 illustrates an example of an operating mode of the pixel of FIG. 2;

FIG. 4 is a cross-section view schematically illustrating another example of a pixel of an image sensor according to an embodiment;

FIG. 5 illustrates an example of an operating mode of the pixel of FIG. 4; and

FIG. 6 illustrates another example of an operating mode of the pixel of FIG. 4.

### DETAILED DISCUSSION

The same elements have been designated with the same reference numerals in the different drawings. In particular, the structural and/or functional elements common to the different embodiments may be designated with the same reference numerals and may have identical structural, dimensional, and material properties.

For clarity, only those steps and elements which are useful to the understanding of the described embodiments have been shown and are detailed. In particular, in the embodiments of image sensors in sequential 3D technology described hereafter, the various steps of forming of the pixel elements of the first and second conductive substrate have not been detailed, the implementation of these steps being within the abilities of those skilled in the art based on the indications of the present disclosure.

Throughout the present disclosure, the term “connected” is used to designate a direct electrical connection between circuit elements with no intermediate elements other than conductors, whereas the term “coupled” is used to designate an electrical connection between circuit elements that may be direct, or may be via one or more intermediate elements.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., unless otherwise specified, it is referred to the orientation of the drawings, it being understood that, in practice, the described devices may be oriented differently.

The terms “about”, “substantially”, and “approximately” are used herein to designate a tolerance of plus or minus 10%, preferably of plus or minus 5%, of the value in question.

According to an aspect of an embodiment, an image sensor comprising a plurality of pixels is provided, each pixel comprising a photogate detector coupled to a readout circuit via a transfer gate, the sensor being formed in sequential 3D technology inside and on top of two stacked semiconductor substrates. More particularly, the photogate detector and the transfer gate are formed inside and on top of a first semiconductor substrate, and the readout circuit is totally or partly formed inside and on top of a second semiconductor substrate arranged on the first substrate, the sensor being intended to be illuminated on the side of the surface of the first substrate opposite to the second substrate.

An advantage of this embodiment is that photogate detectors are relatively little sensitive to the additional thermal budget seen during the forming of the pixel elements formed inside and on top of the second semiconductor substrate. Thus, the performance of the detectors previously formed in the first semiconductor substrate is not degraded due to the subsequent forming of the readout circuit in the second semiconductor substrate.

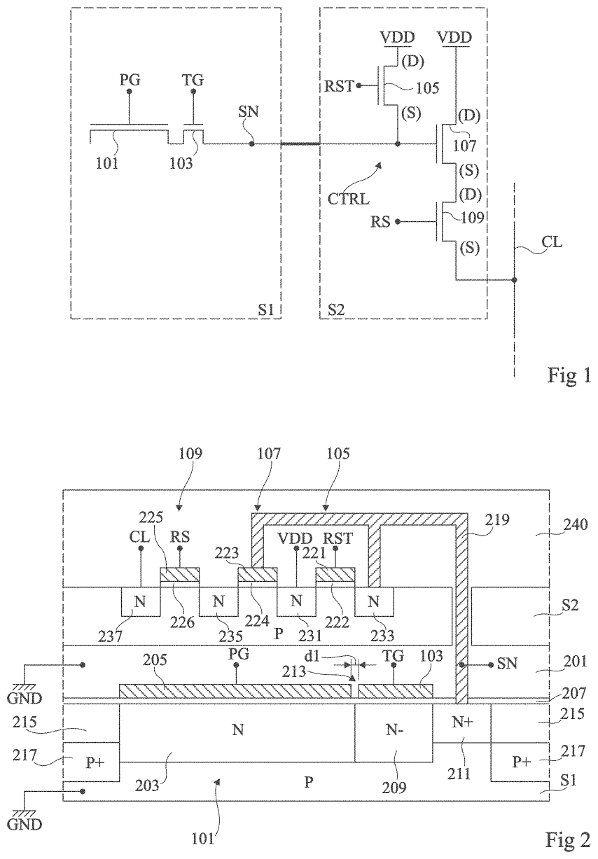

FIG. 1 is an electric diagram of an example of a pixel of an image sensor according to an embodiment.

The pixel of FIG. 1 comprises a photogate photon detector 101, coupled to a capacitive sense node SN of the pixel via a transfer gate 103. The term photogate detector here means a planar MOS capacitor comprising a stack of a doped region formed in the upper portion of a semiconductor substrate and defining a photogenerated charge storage region, of a dielectric layer coating the upper surface of the substrate, and of a conductive gate, for example, made of doped polysilicon, coating the upper surface of the dielectric layer. Transfer gate here means a planar conductive gate insulated from the gate of detector 101, coating a portion of the substrate located between the charge storage region of detector 101, and a readout region connected to node SN and insulated from the substrate by a dielectric layer.

Sense node SN is coupled, preferably connected, to a pixel readout circuit CTRL. In the example of FIG. 1, readout circuit CTRL comprises a reset MOS transistor 105 coupling, by its conduction nodes (source and drain), sense node SN to a node of application of a high power supply potential VDD of the pixel, for example, common to all the sensor pixels. In the shown example, transistor 105 is an N-channel MOS transistor, having its source (S) coupled, preferably connected, to node SN and having its drain (D) coupled, preferably connected, to node VDD. Readout circuit CTRL further comprises a readout MOS transistor 107 assembled as a follower source, having its gate coupled, preferably connected, to node SN. In the shown example, transistor 107 is an N-channel MOS transistor having its drain (D) coupled, preferably connected, to node VDD. Readout circuit CTRL further comprises a readout selection MOS transistor 109 coupling, by its conduction nodes, the source (S) of readout transistor 107 to a conductive output track CL of the pixel, which may be common to a plurality of pixels of the sensor. In the shown example, transistor 109 is an N-channel MOS transistor having its drain (D) coupled, preferably connected, to the source (S) of transistor 107 and having its source (S) coupled, preferably connected, to conductive output track CL.

In operation, the variations of the potential of sensor node SN are transferred onto source 107. The pixel receives control signals PG, TG, RST, and RS respectively applied to the gate of detector 101, to transfer gate 103, and to the gates of transistors 105 and 109.

As an example, the pixel may be controlled as follows:

During a pixel integration phase (preceded by a step of resetting photogate detector 101), control signals PG and TG are selected to insulate from sense node SN the photogenerated charge storage region of detector 101. The electric charges generated in detector 101 under the effect of light then cause a progressive decrease in the potential of the charge storage region of detector 101.

Before the end of the integration phase, reset transistor 105 may be turned on to reset the potential of sense node SN to potential VDD, after which transistor 105 may be turned off to isolate node SN from node VDD.

After the step of resetting node SN, the potential of node SN may be read and stored during a first readout step, to form a reference for a subsequent step of measuring the quantity of photogenerated charges stored in the storage region of detector 101. To achieve this, selection transistor 109 is turned on, so that the potential of node SN is transferred onto output track CL, via transistors 107 and 109. The potential of track CL may then be read and stored, via a readout circuit, not shown.

After the first readout step, the levels of control signals PG and/or TG are modified to cause the transfer of the photogenerated charges stored in detector 101 onto sense node SN. The voltage at node SN then decreases by a value representative of the amount of photogenerated charges stored in detector 101, and thus of the light intensity received by detector 101, during the integration.

The potential of node SN, transferred onto output track CL by transistors 107 and 109, can then be read again during a second readout step, by a readout circuit, not shown.

The value of the output signal of the pixel is for example equal to the difference between the reference potential read out from track CL during the first readout step and the potential read out from track CL during the second readout step.

An advantage of such a readout method is that it enables to at least partly do away with certain noise sources, such as the reset noise introduced by transistors 105.

As an example, the pixels are arranged in an array, the pixels of a same column sharing a same output conductive track CL and the pixels of different columns being coupled to different output conductive tracks CL. On acquisition of an image, the pixels are for example initialized, and then integrate the incident light flow before being read from row by row. For this purpose, in each row of sensor pixels, the conductive gates of the detectors 101 of the pixels in the row may be connected to a same conductive track (not shown) receiving a control signal PG common to all the pixels in the row, the transfer gates 103 of the pixels in the row may be connected to a same conductive track (not shown) receiving a control signal TG common to all the pixels in the row, the gates of the transistors 105 of the pixels in the row may be connected to a same conductive track (not shown) receiving a control signal RST common to all the pixels in the row, and the gates of the transistors 109 of the pixels in the row may be connected to a same conductive track (not shown) receiving a control signal RS common to all the pixels in the row.

As schematically illustrated in FIG. 1 by frames in broken lines, detector 101 and transfer gate 103 are formed inside and on top of a first semiconductor substrate S1, and readout circuit CTRL is formed inside and on top of a second semiconductor substrate S2, arranged on substrate S1. FIG. 1 further shows in the form of a thick line, an insulated conductive via crossing substrate S2 and connecting readout circuit CTRL, and more particularly the source of transistor 105 and the gate of transistor 107, to the sense node SN located on substrate S1.

FIG. 2 is a cross-section view schematically illustrating an embodiment of the pixel of FIG. 1.

In this example, the sensor comprises a lower semiconductor substrate S1 and an upper semiconductor substrate S2, separated from each other by an intermediate insulating layer 201. Substrates S1 and S2 are for example made of single-crystal silicon. In this example, substrates S1 and S2 are P-type doped and are intended to be coupled to a node of application of a low power supply potential GND of the sensor, for example, the ground. As an example, substrates S1 and S2 each have a doping level in the range from 5*10¹⁴ to 3*10¹⁵ atoms/cm³.

In each pixel, the detector 101 and the transfer gate 103 of the pixel are formed inside and On top of a portion of substrate S1, the control transistors 105, 107, and 109 of the pixel being formed inside and on top of a portion of substrate S2, located opposite (that is, vertically aligned with) the corresponding portion of substrate S1.

Detector 101 comprises an N-type doped region 203 formed in substrate S1, for example, by implantation. In this example, region 203 extends vertically from the upper surface of substrate S1, down to an intermediate depth of substrate S1. As an example, region 203 extends in substrate S1 down to a depth in the range from 0.5 to 3 micrometers. As a variation, region 203 may extend across a more significant thickness, possibly across the entire height of substrate S1. Further, region 203 is not necessarily formed by implantation but may for example correspond to a portion of an in-situ doped epitaxial layer. Laterally, region 203 for example extends over the most part of the pixel surface. Region 203 defines a photogenerated charge storage region of detector 101. The doping level of region 203 is preferably relatively high, for example, in the range from 10¹⁷ to 10¹⁸ atoms per cm³. An advantage resulting from such a high doping level is that this enables to make the impact of the additional thermal budget seen by detector 101 low or negligible upon forming of the upper pixel elements inside and on top of substrate S2. In particular, this enables to limit the modifications of the doping profile of region 203 in the case of a diffusion of P-type dopant elements in region 203. Preferably, region 203 is arsenic-doped, which has the advantage of being lightly diffusing in silicon.

It should be noted that in an alternative embodiment (not shown), storage region 203 may be buried, that is, separated from the upper surface of substrate S1 (and thus from dielectric layer 207) by a P-type doped substrate region. This particularly enables to limit the trapping of photogenerated charges at the interface between storage region 203 and insulating layer 207.

Detector 101 further comprises a planar conductive gate 205, for example, made of polysilicon, arranged above the upper surface of substrate S1, opposite storage region 203, and separated from the upper surface of substrate S1 by a dielectric layer 207, for example, made of silicon oxide. As an example, the thickness of layer 207 is in the range from 20 to 100 nanometers.

In this example, dielectric layer 207 is arranged on top of and in contact with the upper surface of substrate S1, and conductive gate 205 is arranged on top of and in contact with the upper surface of dielectric layer 207. Dielectric layer 207 and conductive gate 205 for example extend over substantially the entire surface of region 203. Dielectric layer 207 forms the insulator of the MOS capacitor forming detector 101. In this example, dielectric layer 207 continuously extends over substantially the entire surface of substrate S1, and also forms the gate insulator of the transfer gate 103 of the pixel.

The pixel of FIG. 2 further comprises an N-type doped transfer region 209 formed in substrate S1, for example, by implantation. Region 209 has a lateral edge in contact with a lateral edge of storage region 203 of the pixel. In this example, region 209 has a doping level (N−) smaller than that of region 203, for example, a doping level in the range from 10¹⁶ to 10¹⁷ atoms/cm³. The described embodiments are however not limited to this specific case. Transfer region 209 vertically extends from the upper surface of substrate S1, down to an intermediate depth of substrate S1, for example, down to a depth substantially equal to that of storage region 203. Preferably, region 209 is arsenic-doped.

Conductive transfer gate 103 of the pixel, for example, made of polysilicon, is arranged on top of and in contact with the upper surface of dielectric layer 207, opposite transfer region 209. As an example, transfer gate 103 extends over substantially the entire surface of transfer region 209. In the shown example, the transfer gate 103 and the conductive gate 205 of detector 101 are formed in a same conductive level, for example, corresponding to a transistor gate forming level in a CMOS circuit manufacturing process. Gate 103 and gate 205 are separated from each other by an insulating space 213 located vertically in line with the junction between storage region 203 and transfer region 209. Preferably, the distance di laterally separating transfer gate 103 from gate 205 of detector 101 is short, for example, shorter than 0.5 μm and preferably shorter than 0.30 μm, which enables to ease the photogenerated charge transfer from storage region 203 to sense node SN.

The pixel of FIG. 2 further comprises an N-type doped readout region 211, formed in substrate S1, for example, by implantation. Readout region 211 is located on the side of transfer region 209 opposite to storage region 203, and has a lateral edge in contact with a lateral edge of transfer region 209. In other words, transfer region 209 extends from storage region 203 to readout region 211. In this example, readout region 211 has a doping level (N+) greater than that of region 203, for example, a doping level in the range from 10¹⁹ to 10²⁰ atoms/cm³. Readout region 211 extends vertically from the upper surface of substrate S1, down to an intermediate depth of substrate S1, preferably down to a depth shorter than that of storage region 203 and than that of transfer region 209.

The lower portion of the pixel may be laterally delimited by a peripheral insulation structure vertically extending in substrate S1. In the shown example, the peripheral insulation structure comprises a shallow insulation trench 215, for example, having a depth smaller than that of storage region 203, filled with an insulating material, for example, silicon oxide and, under trench 215, a P-type doped region 217, having a doping level (P+) greater than that of the substrate. As a variation (not shown), the insulation structure is formed by a shallow trench, for example, having a depth greater than or equal to that of storage region 203, the lateral walls and the bottom of the trench being coated with an insulating laver, for example, made of silicon oxide, the trench then being filled with a conductive material. It is then spoken of a capacitive deep trench insulation or CDTI. In operation, the conductive material filling the trench may be biased, for example, at a negative potential, to cause a storage of holes along the trench at the interface between the trench and storage region 203, and thus neutralize the generation of dark currents. As an example, the conductive material filling the trench is P-type doped polysilicon. In this last case, it is particularly advantageous for storage region 203 to have a high doping level since there is a risk for P-type dopants to diffuse from the trench to region 203, through the insulating layer coating the trench sides. Other peripheral insulation structures may however be provided, for example, trenches entirely filled with insulator, having a depth greater than or equal to that of storage region 203.

Readout region 211 is in contact, by its upper surface, with a metallization 219 forming sense node SN of the pixel.

In the example of FIG. 2, insulating layer 201 forming an interface between substrates S1 and S2, for example, made of silicon oxide, is deposited over the upper surface of substrate S1 after the forming of detector 101 and of transfer gate 103, inside and on top of substrate S1.

Upper substrate S2 is then transferred, for example, by molecular bonding, onto the upper surface of insulating layer 201, after which transistors 105, 107, and 109 of readout circuit CTRL, are formed inside and on top of substrate S2, on the upper surface side of substrate S2.

Metallization 219 is a conductive via extending in an opening vertically crossing substrate S2 and insulating layers 201 and 207, and connects the upper surface of readout region 211 to the gate of transistor 107 and to the source of transistor 105.

Transistors 105, 107, and 109 each comprise a conductive gate 221, respectively 223, respectively 225, for example, polysilicon, arranged above substrate S2 and insulated therefrom by a dielectric layer 222, respectively 224, respectively 226. Gate 223 of transistor 107 is in contact with metallization 219. Gates 221 and 225 of transistors 105 and 109 are in contact with metallizations (not shown) intended to be coupled, preferably connected, respectively to a node of application of reset control signal RST and to a node of application of control signal RS.

N-type doped source/drain regions, for example, having a doping level in the range from 10¹⁹ to 10²⁰ atoms per cm³, are formed in the upper portion of substrate S2, on either side of gates 221, 223, 225 of the transistors. More particularly, an N-type region 231 common to transistors 105 and 107, extending between gate 221 of transistor 105 and gate 223 of the transistor, forms the drain of transistor 105 and the drain of transistor 107. Region 231 is in contact, by its upper surface, with a metallization (not shown) coupled, preferably connected, to a node of application of high power supply potential VDD. An N-type region 233 arranged on the side of gate 221 opposite to region 231 defines the source region of transistor 105. Region 233 is in contact, by its upper surface, with metallization 219 defining sense node SN of the pixel. An N-type region 235 common to transistors 107 and 109, extending between gate 223 of transistor 107 and gate 225 of transistor 109, forms the source of transistor 107 and the drain of transistor 109. An N-type region 237 arranged on the side of gate 225 opposite to region 235 defines the source region of transistor 109. Region 237 is in contact, by its upper surface, with a metallization (not shown) coupled, preferably connected, to the output conductive track CL of the pixel.

In the shown example, an insulating layer 240, for example, made of silicon oxide, is deposited on the upper surface of substrate S2 after the forming of transistors 105, 107, and 109, metallization 219 being at least partly formed in insulating layer 240.

Although it has not been detailed in the drawing, metallizations of connection to conductive gates 205 and 103, intended to be respectively connected to a node of application of the control signal PG of detector 101 and to a node of application of the control signal TG of transfer gate 103, may be formed in insulating layer 201, and/or in insulating layer 240. In this last case, the metallizations may be coupled to conductive gates 205 and 103 by means of vias crossing substrate S2. Preferably, no metallization is formed in insulating layer 201 before the transfer of substrate S2. Indeed, the forming of metallizations in insulating layer 201 before the transfer of substrate S2 would result in significantly restricting the thermal budget available for the forming of the pixel elements formed inside and on top of substrate S2. Further, this would result in introducing metal into the equipment used for the forming of the pixel elements formed inside and on top of substrate S2, which is not desirable. Thus, in a preferred embodiment, the metallizations of connection to conductive gates 205 and 103 are formed in insulating layer 240 and coupled to conductive gates 205 and 103 by means of conductive vias crossing substrate S2.

The sensor described in relation with FIG. 2 is intended to be illuminated on the side of the surface of substrate S1 opposite to substrate S2. Substrate S1 is thus preferably relatively thin, to enable the photogenerated charges to reach storage region 203. A step of thinning substrate S1, from its lower surface, is for example provided after the forming of transistors 105, 107, and 109 in upper substrate S1. As an example, after the thinning, the thickness of substrate S1 is in the range from 3 to 10 micrometers.

Additional layers (not shown) having electric passivation functions and/or optical functions, for example, antireflection functions, may be deposited on the lower surface of substrate S1.

It should be noted that various structural characteristics result from the sequential forming of the 3D assembly forming the sensor of FIG. 2, and distinguish this assembly from a parallel 3D assembly, that is, the assembly of two integrated circuits formed separately from each other, and then placed against each other and connected to each other via their respective metallizations.

It can in particular be noted that in the sensor of FIG. 2, the distance separating the upper surface of substrate S1 from the lower surface of substrate S2, corresponding in the shown example to the cumulated thickness of insulating layers 207 and 201, may be relatively thin, for example, smaller than or equal to 750 nm, for example, in the order of 500 nm.

As a result, the conductive vias formed after the transfer of substrate S2 and crossing substrate S2 to connect components of substrate S2 to components of substrate S1, for example, vias 219, may have relatively low transverse dimensions, for example, a diameter smaller than or equal to 90 nm, which enables to reach a high integration density.

It should further be noted that such vias directly emerge either onto the upper surface of substrate S1, as is the case, in particular, for via 219, or onto the upper surface of conductive gates 103 or 205.

Preferably, gates 103 and 205 are made of polysilicon and no metallization is formed above the upper surface of substrate S1 before the transfer of substrate S2. As a result, there is no line or metal pad of interconnection parallel to substrate S1 and S2 extending between substrates S1 and S2.

It can further be noted that in the sensor of FIG. 2, the transistors of substrate S1 and the transistors of substrate S2 have the same orientation. In particular, semiconductor transfer region 209 (forming the channel region of a transistor having, as source and drain regions, regions 203 and 211 and, as a gate, gate 103) is located on the lower surface side of gate 103. Similarly, transistors 105, 107, and 109 have their respective channel regions located on the lower surface side of their respective gates.

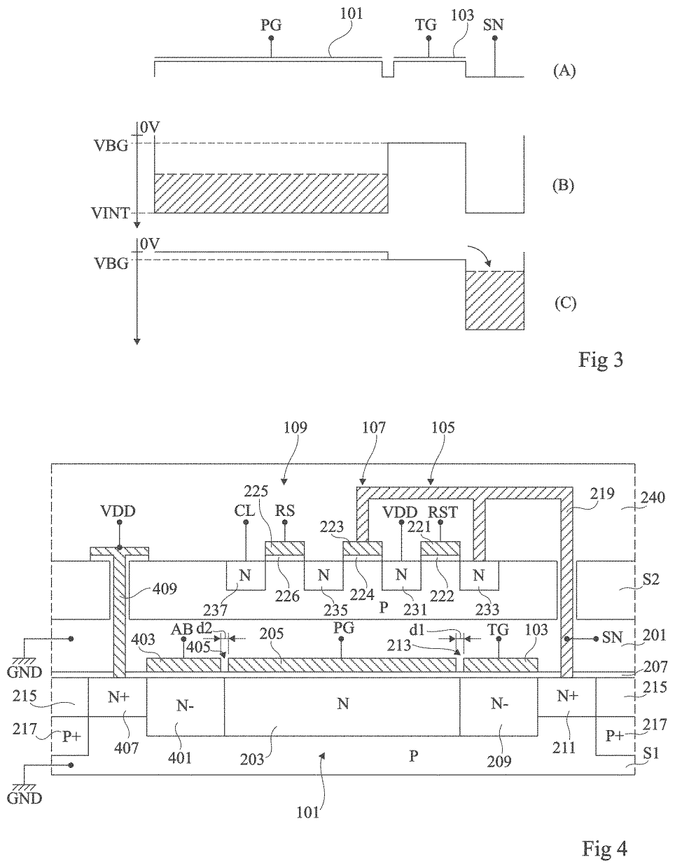

FIG. 3 illustrates an example of an operating mode of the pixel of FIG. 2. The following have been more particularly schematically shown:

in portion (A) of FIG. 3, from left to right, detector 101, transfer gate 103, and. sense node SN;

in portion (B) of FIG. 3, from left to right, the maximum potential levels in storage region 203, in transfer region 209, and in readout region 211 during an integration phase of the pixel; and

in portion (C) of FIG. 3, from left to right, the maximum potential levels in storage region 203, in transfer region 209, and in readout region 211 during a pixel readout phase.

It should be noted that in FIGS. 3(B) and 3(C), the axis of ordinates, representing the potential levels, is oriented downwards, that is, the lower the position on the axis, the higher the potential, and conversely.

During a pixel integration phase (FIG. 3(B)), control potentials PG and TG are selected to insulate photogenerated charge storage region 203 from detector 101 of the readout region 211 of the pixel. In the shown example, a relatively high positive potential is applied to conductive gate 205 of detector 101 (signal PG) and a relatively low positive potential, or a zero or negative potential, is applied to conductive transfer gate 103 (signal TG). As an example, potentials PG and TG are selected so that the maximum potential in storage region 203 (in the absence of photogenerated charges) has a relatively high value VINT, for example, in the order of 2 volts, and so that the maximum potential in transfer region 209 has a relatively low value VTG, for example, in the range from 0.1 to 0.5 volt. A potential well thus forms in storage region 203 and a potential barrier forms at the level of transfer region 209. During the integration, the photogenerated electrons are stored in storage region 203, causing a progressive decrease of the potential of region 203. In FIGS. 3(B) and 3(C), the photogenerated charges are schematically represented by hatched regions.

During the readout phase (FIG. 3(C)), control potentials PG and/or TG are modified to transfer the photogenerated charges stored in region 203 to readout region 211. In the example of FIG. 3, control potential TG of transfer gate 103 is maintained unchanged, while control potential PG is taken down to 0 volt or to a negative value, to lower the maximum potential in storage region 203 below value VBG. As a result, all the photo-generated charges stored in region 203 during the integration phase are transferred into readout region 211. The potential of sense node SN then decreases by a value representative of the quantity of photogenerated charges stored in region 203.

FIG. 4 is a cross-section view schematically illustrating another example of an image sensor pixel according to an embodiment. The pixel of FIG. 4 comprises the same elements as the pixel of FIG. 2, arranged substantially in the same way, and differs from the pixel of FIG. 2 in that it further comprises an antiblooming device enabling to avoid, in case of a saturation of the storage region 203 of the detector 101 of a pixel, for charges photogenerated in this pixel to leak towards neighboring pixels.

The pixel of FIG. 4 comprises an additional N-type doped transfer region 401 formed in substrate S1, for example, by implantation. Region 401 has a lateral edge in contact with a lateral edge of storage region 203 of the pixel. Transfer region 401 is however separate from transfer region 209. As an example, transfer region 401 is located on the side of storage region 203 opposite to transfer region 209. In this example, transfer region 401 has a doping level (N−) lower than that of region 203. As an example, transfer region 401 has a doping level substantially identical to that of transfer region 209. Transfer region 401 extends vertically from the upper surface of substrate S1, down to an intermediate depth of substrate S1, for example down to a depth substantially equal to that of transfer region 209. Preferable, region 401 is doped with arsenic.

The pixel of FIG. 4 further comprises an additional conductive transfer gate 403, for example, made of polysilicon, arranged on top of and in contact with the upper surface of dielectric layer 207, opposite transfer region 401. As an example, transfer gate 403 extends over substantially the entire surface of transfer region 401. Transfer gate 403 is for example formed in the same conductive level as gates 205 and 103. Gate 403 and gate 205 are separated from each other by an insulating space 405 located vertically in line with the junction between storage region 203 and transfer region 401. Preferably, distance d2 laterally separating transfer gate 401 from gate 205 is short, for example, shorter than 0.5 μm, and preferably shorter than 0.3 μm.

The pixel of FIG. 4 further comprises an N-type doped discharge region 407, formed in substrate 51, for example, by implantation. Region 407 is located on the side of transfer region 401 opposite to storage region 203, and has a lateral edge in contact with a lateral edge of transfer region 401. In other words, transfer region 401 extends from storage region 203 to region 407. In this example, region 407 has a doping level (N+) higher than that of region 203, for example, a doping level substantially equal to that of readout region 211. Region 407 extends vertically from the upper surface of substrate S1 down to an intermediate depth of substrate S1, for example, down to a depth substantially equal to that of readout region 211. Preferably, region 407 is doped with arsenic.

Region 407 is in contact, by its upper surface, with a metallization 409 coupled, preferably connected, to a node of application of high power supply potential VDD. As an example, metallization 409 extends in an opening vertically crossing substrate S2 and insulating layers 201 and 207.

Additional transfer gate 403 is intended to be connected to a node of application of a signal AB of control of the antiblooming device. Preferably, the metallizations of connection to gate 403 are formed in insulating layer 240 coating substrate S2, and are coupled to gate 403 via a conductive via crossing substrate S2.

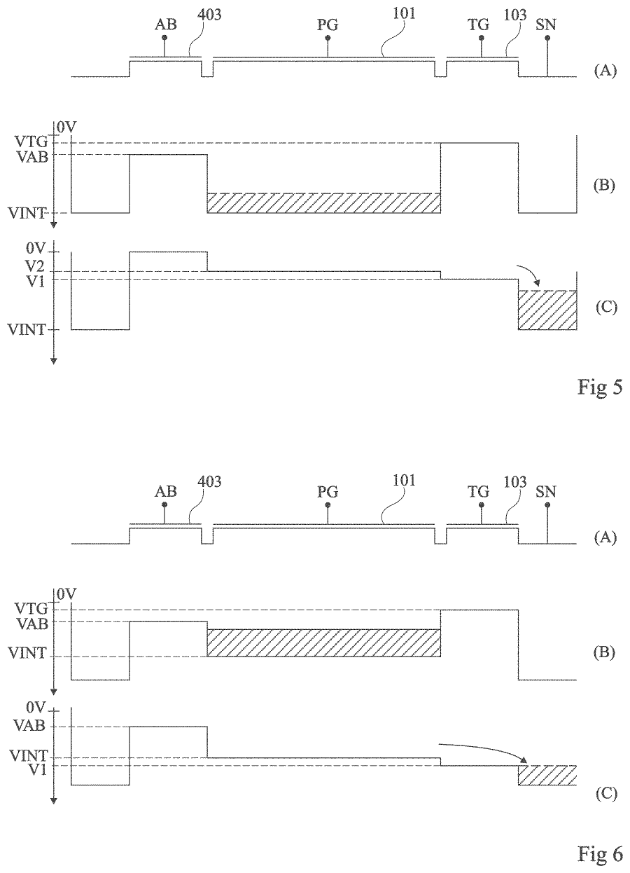

FIG. 5 illustrates an example of an operating mode of the pixel of FIG. 4. The following have been more particularly schematically shown:

in portion (A) of FIG. 5, from left to right, detector 101, transfer gate 403, detector 101, transfer gate 103, and sense node SN;

in portion (B) of FIG. 5, from left to right, the maximum potential levels in transfer region 401, in storage region 203, in transfer region 209, and in readout region 211 during an integration phase of the pixel; and

in portion (C) of FIG. 5, from left to right, the maximum potential levels in storage region 203, in transfer region 401, in storage region 203, in transfer region 209, and in readout region 211 during a pixel readout phase.

It should be noted that in FIGS. 5(B) and 5(C), the axis of ordinates, representing the potential levels, is oriented downwards, that is, the lower the position on the axis, the higher the potential, and conversely.

During a pixel integration phase (FIG. 5(B)), control potentials AB, PG, and TG are selected to insulate photogenerated charge storage region 203 from detector 101 of the readout region 211 and from discharge region 407 of the pixel. In the shown example, a relatively high positive potential is applied to conductive gate 205 of detector 101 (signal PG) and a relatively low positive potential, or a zero or negative potential, is applied to transfer gate 103 (signal TG) and to the additional transfer gate 403 (signal AB). As an example, potentials AB, PG, and TG are selected so that the maximum potential in storage region 203 (in the absence of photogenerated charges) has a relatively high value VINT, for example, in the order of 2.5 volts, so that the maximum potential in transfer region 209 has a relatively low value VTG, for example, in the order of 0.2 volt, and so that the maximum potential in transfer region 401 has a relatively low value VAB, however greater than value VTG, for example, in the order of 0.5 volt A potential well thus forms in storage region 203, and potential harriers form at the level of transfer regions 209 and 401, it being understood that the height of the potential barrier at the level of transfer region 401 is greater than at the level of transfer region 209. During the integration, the photogenerated electrons are stored in storage region 203, causing a progressive decrease in the potential of region 203. When the potential of storage region 203 reaches value VAB, the additional photogenerated charges generated in detector 101 are discharged towards region 407 and then towards the high power supply node VDD of the pixel.

During the readout phase (FIG. 5(C)), control potentials AB, PG, and/or TG are modified to transfer the photogenerated charges stored in region 203 towards readout region 211. In the example of FIG. 5, control potential AB is taken down to 0 volt or to a negative value, to lower the maximum potential in region 401 below value VAB, for example, to 0 volt. Control potentials PG and TG are respectively decreased and increased, to create a potential step resulting in transferring to readout region 211 all the photogenerated charges stored in region 203. More particularly, potentials PG and TG are selected so that the maximum potential in transfer region 209 is taken to a value V1 greater than value VTG but smaller than the potential of readout region 211, for example, a value V1 in the order of 1.5 volts, and so that the maximum potential in storage region 203 is taken back to a value V2 greater than the value of the potential of transfer region 401 but smaller than value V1, for example, a value V2 in the order of 1 volt. As a result, all the photogenerated charges stored in region 203 during the integration phase are transferred into readout region 211 The potential of sense node SN then decreases by a value representative of the quantity of photogenerated charges stored in region 203.

FIG. 6 is a representation similar to FIG. 5, illustrating another example of an operating mode of the pixel of FIG. 4.

The control mode of FIG. 6 differs from the control mode of FIG. 5 mainly in that, in the example of FIG. 6, during the pixel integration phase (FIG. 6(B)), the maximum potential VINT in the storage region 203 of the detector is smaller than in the example of FIG. 5, for example, in the order of 1.5 volts. During the pixel readout phase (FIG. 6(C)), the control potentials PG and AB of detector 101 remain unchanged. Control potential TG is increased so that the maximum potential in transfer region 209 is taken to a value V1 greater than value VINT but smaller than the potential of readout region 211, for example, a value V1 in the order of 2 volts. As a result, all the photogenerated charges stored in region 203 during the integration phase are transferred into readout region 211. The potential of sense node SN then decreases by a value representative of the quantity of photogenerated charges stored in region 203.

It should be noted that the anti-blooming device of FIG. 4 may also be used to control the pixel integra time. Indeed, by biasing gate 403 to a high state during the beginning of the integration phase, the photogenerated charges are directly discharged into drain 407 and thereby are not stored in region 203. The starting of the integration may thus be controlled by the switching to the low state of the level applied to gate 403.

Various embodiments and variations have been described. Those skilled in the art will understand that certain features of these various embodiments and variations may be combined, and other variations will occur to those skilled in the art. In particular, the described embodiments are not limited to the examples of dimensions and of materials described hereabove. Further, the described embodiments are not limited to the specific example of readout circuit described hereabove.

Further, the described embodiments are not limited to the examples described hereabove where the sensor comprises one readout circuit per pixel. As a variation, a same readout circuit may be shared by a plurality of neighboring pixels. As an example, the sensor pixels are distributed in groups of four neighboring pixels, the sensor comprising one readout circuit per group of four neighboring pixels.

Finally, the practical implementation of the described embodiments and variations is within the abilities of those skilled in the art based on the functional indications given hereabove.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. An image sensor comprising a plurality of pixels, each pixel comprising a photogate detector coupled to a readout circuit via a first conductive transfer gate, wherein the photogate detector and the first transfer gate are formed inside and on top of a first semiconductor substrate, and the readout circuit is formed inside and on top of a second semiconductor substrate arranged on the first substrate, the sensor being intended to be illuminated on the side of the surface of the first substrate opposite to the second substrate, wherein the first conductive transfer gate is arranged on the side of a surface of the first substrate facing the second substrate and wherein the readout circuit comprises at least one MOS transistor comprising a conductive gate arranged on the side of a surface of the second substrate opposite to the first substrate.

2. The sensor of claim 1, wherein the photogate detector comprises:
a storage region having a conductivity type opposite to that of the first substrate, formed in the first substrate;
a dielectric layer coating the storage region; and
a conductive gate coating the dielectric layer.

3. The sensor of claim 2, wherein the distance between the gate of the photogate detector and the first transfer gate is shorter than 0.5 micrometer.

4. The sensor of claim 1, wherein first substrate is of type P and storage region is of type N.

5. The sensor of claim 4, wherein the doping level of the storage region is in the range from 10¹⁷ to 10¹⁸ atoms per cm³.

6. The sensor of claim 4, wherein the storage region is doped with arsenic.

7. The sensor of claim 1, further comprising, under the first transfer gate, a first transfer region having a conductivity type opposite to that of the first substrate, formed in the first substrate, the first transfer region being insulated from the first transfer gate by a dielectric layer.

8. The sensor of claim 1, wherein the photogate detector is further coupled to a discharge node via a second conductive transfer gate formed on the first conductive substrate.

9. The sensor of claim 1, wherein the distance between the first and second substrates is shorter than or equal to 750 nm.

10. The sensor of claim 1, comprising no metal interconnection tracks parallel to the first and second substrates between the first and second substrates.

11. The sensor of claim 1, wherein the photogate detector is coupled to the readout circuit by means of a via located in an opening crossing the second substrate and emerging onto the upper surface of the first substrate.

12. The sensor of claim 11, wherein said via has a diameter smaller than or equal to 90 nm.

13. A method of manufacturing an image sensor comprising a plurality of pixels, each pixel comprising a photogate detector coupled to a readout circuit via a first conductive transfer gate, wherein the photogate detector and the first transfer gate are formed inside and on top of a first semiconductor substrate, and the readout circuit is formed inside and on top of a second semiconductor substrate arranged on the first substrate, the sensor being intended to be illuminated on the side of the surface of the first substrate opposite to the second substrate, comprising the successive steps of:
forming the photogate detector and the first transfer gate inside and on top of the first substrate;
depositing the second substrate on the first substrate; and
forming the readout circuit inside and on top of the second substrate.

14. The method of claim 13, wherein the first conductive transfer gate is arranged on the side of a surface of the first substrate facing the second substrate and wherein the readout circuit comprises at least one MOS transistor comprising a conductive gate arranged on the side of a surface of the second substrate opposite to the first substrate.

15. The method of claim 13, wherein the photogate detector comprises:
a storage region having a conductivity type opposite to that of the first substrate, formed in the first substrate;
a dielectric layer coating the storage region; and
a conductive gate coating the dielectric layer.

16. The method of claim 15, wherein the distance between the gate of the photogate detector and the first transfer gate is shorter than 0.5 micrometer.

17. The method of claim 15, wherein the storage region is doped with arsenic.

18. The method of claim 13, wherein the photogate detector is further coupled to a discharge node via a second conductive transfer gate formed on the first conductive substrate.

19. The method of claim 13, wherein the photogate detector is coupled to the readout circuit by means of a via located in an opening crossing the second substrate and emerging onto the upper surface of the first substrate.

20. The method of claim 19, wherein said via has a diameter smaller than or equal to 90 nm.
